(19) United States
(12) Patent Application Publication
(10) Pub. No.: US 2013/0001795 A1
(43) Pub. Date: Jan. 3, 2013

(54) Wafer Level Package and a Method of Forming the Same

(75) Inventors: Teck Guan LIM, Singapore (SG); Ying Ying Lim, Singapore (SG); Yee Mong Khoo, Singapore (SG); Navas Khan Oratti Kalandar, Singapore (SG); Faxing Che, Singapore (SG); Ser Choong Chong, Singapore (SG); Soon Wee David Ho, Singapore (SG); Shan Gao, Singapore (SG); Rui Li, Singapore (SG)

(73) Assignee: Agency for Science, Technology and Research

(21) Appl. No.: 13/407,295

(22) Filed: Feb. 28, 2012

(30) Foreign Application Priority Data
Feb. 28, 2011 (SG) 201101428-9

(51) Int. Cl. H01L 23/48

(52) U.S. Cl. 257/774; 257/E23.011; 257/528

(57) ABSTRACT

A wafer level package is provided. The wafer level package includes at least one chip with at least one electronic component, and at least one connecting chip with at least one through-silicon via, wherein the at least one through-silicon via is electrically coupled to the at least one chip. Further embodiments relate to a method of forming the wafer level package.

### CROSS-REFERENCE TO RELATED APPLICATION

This application claims the benefit of priority of Singapore patent application No. 201101428-9, filed 28 Feb. 2011, the content of it being hereby incorporated by reference in its entirety for all purposes.

### TECHNICAL FIELD

Various embodiments relate to a wafer level package and a method of forming the wafer level package.

### BACKGROUND

Embedded wafer level packaging (EMWLP) is a cost effective solution to provide fan-out for the shrinking chip size. In this process, the known good bare die is picked and placed in a reconfigured or rebuilt wafer, with electrical line then designed to connect the device I/O to a suitable distance for bumping process. In this way, the EMWLP technology does not require additional substrate for the fan out. The success of this packaging technology and the emerging of 3D integration have created a requirement of electrical via in the packaging substrate.

Currently, the EMWLP via is formed by laser ablation followed by electroless copper (Cu) plating. However, this process has several limitations. The laser ablation process is not a batch process and hence time consuming. In addition, it has a large aspect ratio, typically at the ratio of about 1:1.

### SUMMARY

According to an embodiment, a wafer level package is provided. The wafer level package may include at least one chip including at least one electronic component, and at least one connecting chip including at least one through-silicon via, wherein the at least one through-silicon via is electrically coupled to the at least one chip.

According to an embodiment, a method of forming a wafer level package is provided. The method may include providing at least one chip including at least one electronic component within a mold compound, providing at least one connecting chip including at least one through-silicon via within the mold compound, and electrically coupling the at least one through-silicon via to the at least one chip.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1A shows a schematic block diagram of a wafer level package, according to various embodiments.

FIG. 1B shows a schematic block diagram of a wafer level package, according to various embodiments.

FIG. 2 shows a flow chart illustrating a method of forming a wafer level package, according to various embodiments.

FIG. 3 shows a cross sectional view of a wafer level package, according to various embodiments.

FIG. 4 shows a cross sectional view of a wafer level package, according to various embodiments.

FIGS. 5A to 5D show cross-sectional views of a fabrication process to manufacture a wafer level package, according to various embodiments.

FIG. 6 shows a plot of simulated results for the vias of the wafer level package of various embodiments.

FIGS. 7A and 7B show respectively a perspective exploded view and a perspective view, when assembled, of a filter, according to various embodiments.

FIG. 7C shows a cross sectional view of a wafer level package incorporating a cavity filter, according to various embodiments.

FIG. 8 shows a plot of filter response of the embedded TSV cavity filter of various embodiments.

### DETAILED DESCRIPTION

The following detailed description refers to the accompanying drawings that show, by way of illustration, specific details and embodiments in which the invention may be practiced. These embodiments are described in sufficient detail to enable those skilled in the art to practice the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

Embodiments described in the context of one of the methods or devices are analogously valid for the other method or device. Similarly, embodiments described in the context of a method are analogously valid for a device, and vice versa.

In the context of various embodiments, the phrase “at least substantially” may include “exactly” and a variance of +/−5% thereof. As an example and not limitations, “A is at least substantially same as B” may encompass embodiments where A is exactly the same as B, or where A may be within a variance of +/−5%, for example of a value, of B, or vice versa.

In the context of various embodiments, the term “about” as applied to a numeric value encompasses the exact value and a variance of +/−5% of the value.

As used herein, the term “and/or” includes any and all combinations of one or more of the associated listed items.

Various embodiments may provide a wafer level package (e.g. an embedded wafer level package (EMWLP)) and a method of forming the same. Various embodiments may further provide embedded wafer level packaging (EMWLP) vertical interconnect using through-silicon via(s) (TSV) and a method of forming the same.

Various embodiments may provide a connecting chip, e.g. a through-silicon via (TSV) chip (e.g. a prefabricated TSV chip) with one via or multiple vias (TSVs), integrated in the bare die embedding process to provide vertical interconnect(s) or electrical via(s) in the wafer level package (e.g. EMWLP). Different via designs (e.g. diameter and/or pitch) may be implemented using multiple TSV chips. As the TSV and the TSV chip is a silicon (Si) wafer fabrication process, the via may have a very high aspect ratio, typically more than about 1:10, which may help to reduce the overall EMWLP size and cost.

Various embodiments may provide a through-silicon via (TSV) chip having small via diameter and fine pitch. The through-silicon via (TSV) chip may not be affected by moisture due to its silicon (Si) material.

Various embodiments may provide a wafer level package of a smaller area, with greater design flexibility and where the TSV chip may be located at any required positions within the wafer level package. Various embodiments may provide a passive circuit design using the TSV chip, where the input and output ports of the passive circuit may be positioned on opposite sides of the TSV chip, which also provides 3D interconnections. Various embodiments may not require any packaging region.

In various embodiments, the method of forming via in the embedded wafer level packaging (EMWLP) using TSV may not require additional process as the TSV or TSV chip is embedded in the same process as the devices or electrical components. In various embodiments, after back grinding of the TSV to the required thickness/height, the device may be connected to the TSV using one or more redistribution layers (RDL). Therefore, the device may be electrically connected to the other side of the substrate through the TSV. In various embodiments, the TSV may be part of a passive structure or passive circuit.

The fabrication process of various embodiments is a batch process, is simpler and may not require additional integration process.

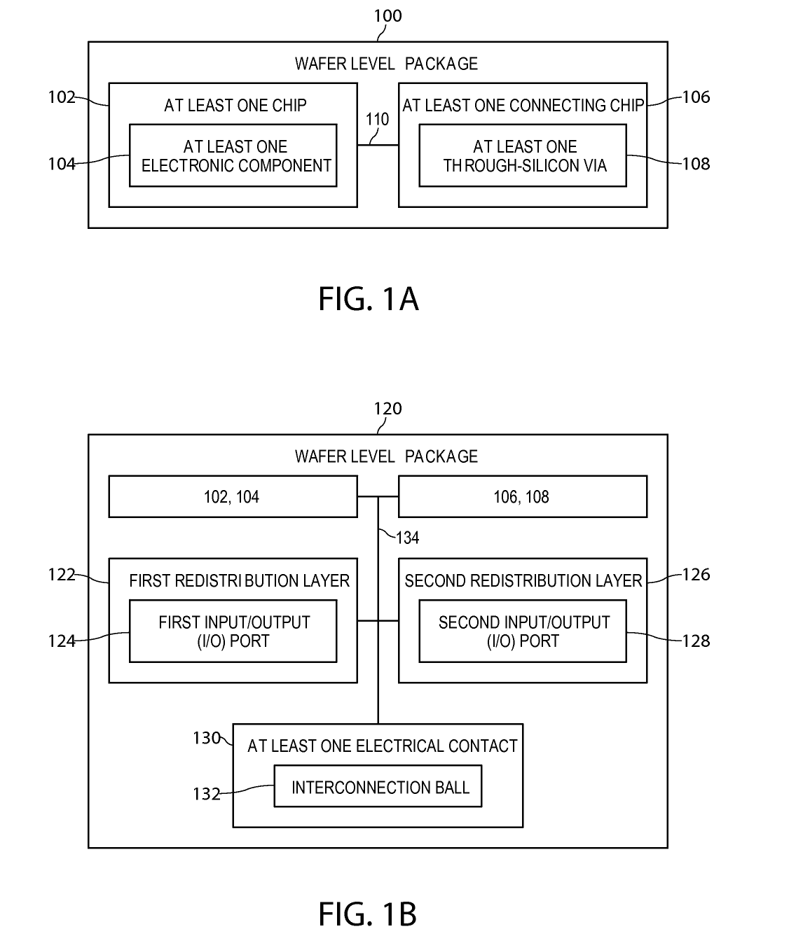

FIG. 1A shows a schematic block diagram of a wafer level package 100, according to various embodiments. The wafer level package 100 includes at least one chip (e.g. a device chip) 102 including at least one electronic component 104, and at least one connecting chip 106 including at least one through-silicon via (TSV) 108, wherein the at least one through-silicon via (TSV) 108 is electrically coupled to the at least one chip 102. The at least one through-silicon via (TSV) 108 may be electrically coupled to the at least one electronic component 104. In FIG. 1A, the line represented as 110 is illustrated to show the relationship between the different components, which may include electrical coupling and/or mechanical coupling.

In the context of various embodiments, the at least one connecting chip 106 may include a plurality of connecting chips (i.e. the wafer level package 100 may include a plurality of connecting chips), and/or the at least one electronic component 104 may include a plurality of electronic components (i.e. the wafer level package 100 or the at least one chip 102 may include a plurality of electronic components), and/or the at least one chip 102 may include a plurality of chips (i.e. the wafer level package 100 may include a plurality of chips).

In the context of various embodiments, the at least one through-silicon via 108 may have an aspect ratio of between about 1:2 and about 1:10, for example between about 1:2 and about 1:5 or between about 1:5 and about 1:10.

In the context of various embodiments, the at least one through-silicon via 108 may have an at least substantially circular shape. The at least one through-silicon via 108 may have a diameter of between about 10 μm and about 100 μm, for example between about 10 μm and about 50 μm, between about 10 μm and about 20 μm or between about 50 μm and about 100 μm. However, it should be appreciated that other values or dimensions may be provided. In addition, it should be appreciated that the at least one through-silicon via 108 may have other shapes, for example square, rectangular, oval or elliptical.

In the context of various embodiments, the at least one through-silicon via 108 may have a height of between about 100 μm and about 400 μm, for example about 100 μm and about 200 μm or between about 200 μm and about 400 μm. However, it should be appreciated that other values or dimensions may be provided.

In the context of various embodiments, the at least one through-silicon via 108 may include a plurality of through-silicon vias (i.e. the wafer level package 100 or the at least one connecting chip 106 may include a plurality of through-silicon vias (TSVs)), for example two TSVs, three TSVs, four TSVs or any higher number of TSVs.

In the context of various embodiments where there are a plurality of TSVs, the plurality of TSVs may have a pitch (i.e. period or distance between adjacent TSVs) of a few of tenth of micrometer to a few of hundredth micrometers, for example between about 40 μm and about 500 μm. However, it should be appreciated that other values or dimensions may be provided, for example a range of between about 1 μm and about 40 μm or between about 500 μm and about 1000 μm (i.e. a range of between about 1 μm and about 1000 μm).

In the context of various embodiments, the plurality of TSVs may be arranged in one or more rows, and/or one or more columns, for example the plurality of TSVs may be arranged according to a two-dimensional pattern or grid pattern.

In the context of various embodiments, the connecting chip 106 may have a resistivity of between about 1000 Ω·cm and about 10000 Ω·cm, for example between about 1000 Ω·cm and about 5000 Ω·cm or between about 5000 Ω·cm and about 10000 Ω·cm.

FIG. 1B shows a schematic block diagram of a wafer level package 120, according to various embodiments. The wafer level package 120 includes at least one chip 102 including at least one electronic component 104, and at least one connecting chip 106 including at least one through-silicon via (TSV) 108, which may be similar to the embodiment as described in the context of FIG. 1A.

In various embodiments, the at least one chip 102 has a first surface and a second surface, e.g. two opposed surfaces, such as top and bottom surfaces. In various embodiments, the at least one connecting chip 106 has a first connecting chip surface and a second connecting chip surface, e.g. two opposed connecting chip surfaces, such as top and bottom connecting chip surfaces.

In various embodiments, the first connecting chip surface of the at least one connecting chip 106 and the first surface of the at least one chip 102 may be at least substantially coplanar, and/or the second connecting chip surface of the at least one connecting chip 106 and the second surface of the at least one chip 102 may be at least substantially coplanar.

In various embodiments, the wafer level package 120 further includes a first redistribution layer (RDL) 122 between the first connecting chip surface of the at least one connecting chip 106 and the first surface of the at least one chip 102, wherein the first redistribution layer 122 is configured to electrically couple the at least one through-silicon via 108 of the at least one connecting chip 106 to the at least one chip 102. This may enable an electronic component (e.g. the at least one electronic component 104), which may include an electronic circuit, e.g. including one or more electronic elements, that may be formed on the first surface of the at least one chip 102 to be electrically coupled with the at least one through-silicon via 108. In various embodiments, the first redistribution layer 122 further includes a first input/output (I/O) port 124.

The wafer level package 120 may include a second redistribution layer (RDL) 126 between the second connecting chip surface of the at least one connecting chip 106 and the second surface of the at least one chip 102, wherein the second redistribution layer 126 is configured to electrically couple the at least one through-silicon via 108 of the at least one connecting chip 106 to the at least one chip 102. This may enable an electronic component (e.g. the at least one electronic component 104), which may include an electronic circuit, e.g. including one or more electronic elements, that may be formed on the second surface of the at least one chip 102 to be electrically coupled with the at least one through-silicon via 108. In various embodiments, the second redistribution layer 126 further includes a second input/output (I/O) port 128.

In various embodiments, the first redistribution layer 122 and/or the second redistribution layer 126 electrically couple the at least one through-silicon via (TSV) 108 of the at least one connecting chip 106 to the at least one electronic component 104 of the at least one chip 102. In embodiments where the first redistribution layer 122 and the second redistribution layer 126 are formed, the first surface and the second surface of the at least one chip 102 may be in electrical communication or electrically coupled with each other by means of the at least one through-silicon via (TSV) 108. Therefore, electronic components, including one or more electronic elements, formed on the first surface and the second surface of the at least one chip 102 may be in electrical communication with each other.

It should be appreciated that any number of redistribution layers may be formed between the first connecting chip surface of the at least one connecting chip 106 and the first surface of the at least one chip 102 and/or between the second connecting chip surface of the at least one connecting chip 106 and the second surface of the at least one chip 102. Therefore, there is no restriction in the number of redistribution layers on both sides/surfaces of the at least one connecting chip 106 or the design of the wafer level package 120.

In various embodiments, the wafer level package 120 may further include at least one electrical contact 130 in electrical communication with the first redistribution layer 122. The at least one electrical contact 130 may be or may include an interconnection ball (e.g. a solder ball). The wafer level package 120 may further include at least another electrical contact in electrical communication with the second redistribution layer 126.

In the context of various embodiments, the first redistribution layer 122 and the second redistribution layer 126 includes a conductive material, such as a metal, for example copper or gold.

In FIG. 1B, the line represented as 134 is illustrated to show the relationship between the different components, which may include electrical coupling and/or mechanical coupling.

In the context of various embodiments, the wafer level package 100, 120, may further include a mold compound configured to at least partially encapsulate the at least one chip 102 and the at least one connecting chip 106.

In the context of various embodiments, the at least one connecting chip 106 may be configured to function as a filter, or a diplexer, or a resonator, or a balun, or a coupler, or an antenna or a radiating element.

In the context of various embodiments, the at least one electronic component 104 may be or may include an integrated circuit or an electronic circuit. In the context of various embodiments, the electronic circuit may include at least one active electronic element. It should be appreciated that the electronic circuit may include one or a plurality of active electronic elements. In addition, it should be appreciated that the electronic circuit may also include one or a plurality of passive electronic elements.

In the context of various embodiments, the electronic circuit may include at least one electronic element such as a transistor (e.g. bipolar transistor or a field effect transistor), a diode, a thyristor, a capacitor, an inductor, a transformer, a resistor and/or any combination thereof.

In the context of various embodiments, the electronic circuit may be formed on the first surface and/or the second surface of the at least one chip 102. Therefore, one or more electronic elements may be formed on different surfaces of the at least one chip 102.

In the context of various embodiments, the at least one connecting chip 106 is a silicon (Si) chip. Therefore, the at least one connecting chip 106 is a through-silicon via (TSV) chip.

In the context of various embodiments, the at least one connecting chip 106 may be free of any electronic components.

In the context of various embodiments, the at least one connecting chip 106 may only include the at least one through-silicon via (TSV) 108.

In the context of various embodiments, the at least one electrical contact 130 may enable electrical coupling to another wafer level package and/or external devices.

It should be appreciated that in various embodiments, each of the plurality of chips may include similar or different at least one electronic component, and/or each of the plurality of electronic components may be a similar or a different electronic component, and/or each of the plurality of connecting chips may have at least substantially same or a different design, for example in terms of the pitch, aspect ratio, diameter or height of the at least one through-silicon via.

In the context of various embodiments, a reference to a through-silicon via (TSV) may include a reference to a plurality of through-silicon vias (TSVs).

In the context of various embodiments, the term “wafer level package” means a package where the circuits, devices and/or electronic components are integrated and packaged at the wafer level. Device interconnection and device protection, where metal layers or redistribution layers and the solder bumps are formed to the integrated circuits and devices, are carried out while still in the wafer, prior to wafer dicing.

In the context of various embodiments, the term “redistribution layer” may mean a conductive metal line for rerouting and interconnection to a chip and/or a connecting chip and/or a device and/or an electronic component of the wafer level package of various embodiments. The redistribution layer may be a single layer or a multi-layer thin-film metal, for example formed using photolithography and thin film deposition techniques.

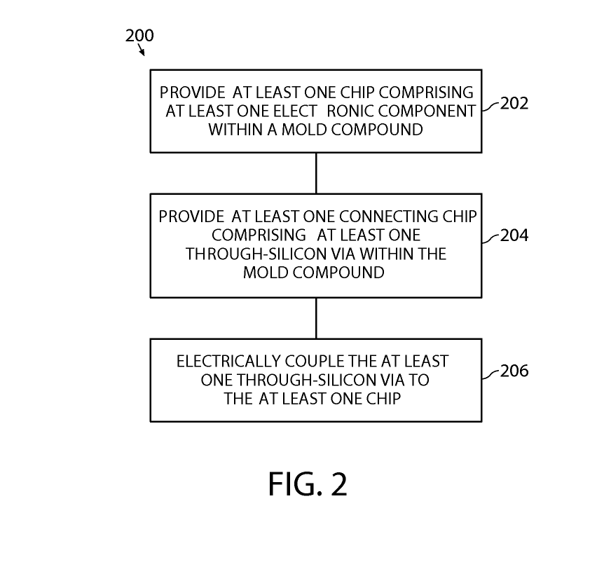

FIG. 2 shows a flow chart 200 illustrating a method of forming a wafer level package (e.g. 100, 120), according to various embodiments.

At 202, at least one chip including at least one electronic component is provided or arranged within a mold compound.

At 204, at least one connecting chip including at least one through-silicon via (TSV) is provided or arranged within the mold compound.

At 206, the at least one through-silicon via is electrically coupled to the at least one chip.

In various embodiments, electrically coupling the at least one through-silicon via to the at least one chip may include forming a first redistribution layer between a first connecting chip surface of the at least one connecting chip and a first surface of the at least one chip, and/or forming a second redistribution layer between a second connecting chip surface of the at least one connecting chip and a second surface of the at least one chip.

In various embodiments, the method may further include coupling or electrically coupling a first input/output (I/O) port to the first redistribution layer, and/or coupling or electrically coupling a second input/output (I/O) port to the second redistribution layer.

In various embodiments, the method may further include forming at least one electrical contact (for example an interconnection ball, e.g. a solder ball) in electrical communication with the first redistribution layer and/or at least one electrical contact (for example an interconnection ball, e.g. a solder ball) in electrical communication with the second redistribution layer.

In various embodiments, the method may include a grinding process for grinding the at least one connecting chip such that the first connecting chip surface and the first surface of the at least one chip are at least substantially coplanar and/or such that the second connecting chip surface and the second surface of the at least one chip are at least substantially coplanar. This may include mechanical grinding or chemical mechanical planarization (CMP).

In various embodiments, the grinding process is carried out prior to forming the first redistribution layer and the second redistribution layer. In alternative embodiments, the grinding process may not be required if the thicknesses of the at least one chip and the at least one connecting chip are at least substantially the same.

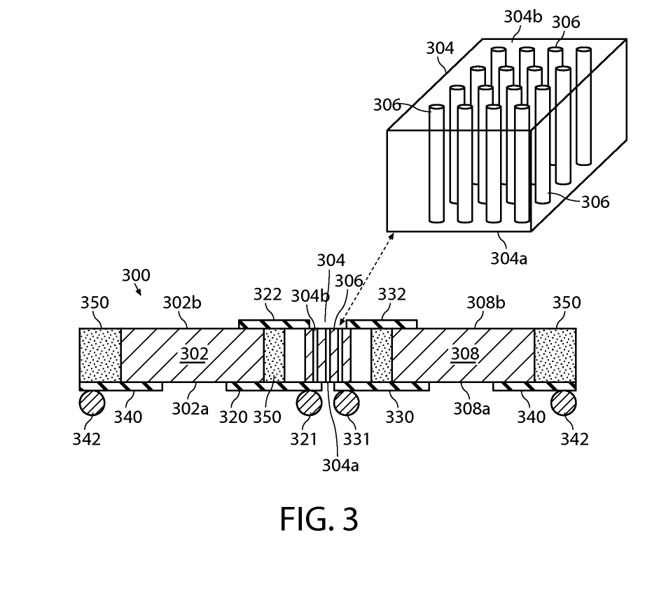

FIG. 3 shows a cross sectional view of a wafer level package 300, according to various embodiments. The wafer level package 300 may be a through-silicon via (TSV) EMWLP integrated structure (e.g. an EMWLP structure integrated with TSV). Such a wafer level package 300 may provide a high density of vias and a smaller overall package dimension.

The wafer level package 300 includes a chip (e.g. a device or device chip) 302. The chip 302 may include one or more electronic components (not shown). The wafer level package 300 further includes a connecting chip (e.g. a TSV chip) 304. In the embodiment shown in FIG. 3, the connecting chip 304 is a through-silicon via (TSV) chip including a plurality of through-silicon vias (TSVs), for example as represented by 306, having an at least substantially circular shape or cross-section. The plurality of TSVs 306 may be arranged in a two-dimensional pattern or grid pattern. The wafer level package 300 may include another chip (e.g. a device or device chip) 308. The chip 308 may include one or more electronic components (not shown).

As shown in FIG. 3, the connecting chip 304 may be embedded or sandwiched between the chips 302, 308, where the connecting chip 304 may be used to provide electrical vertical interconnections for one or two sides (e.g. two opposed sides) of the substrate of each of the chips 302, 308.

The chip 302 includes two opposed surfaces such as a bottom surface (a first surface) 302a and a top surface (a second surface) 302b. The chip 308 includes two opposed surfaces such as a bottom surface (a first surface) 308a and a top surface (a second surface) 308b. The connecting chip 304 includes two opposed connecting chip surfaces, such as a bottom connecting chip surface (a first surface) 304a and a top connecting chip surface (a second surface) 304b, where the plurality of vias 306 may be exposed through the bottom connecting chip surface 304a and the top connecting chip surface 304b.

As shown in FIG. 3, the bottom connecting chip surface 304a of the connecting chip 304 is at least substantially coplanar with the bottom surface 302a of the chip 302 and the bottom surface 308a of the chip 308. The top connecting chip surface 304b of the connecting chip 304 is at least substantially coplanar with the top surface 302b of the chip 302 and the top surface 308b of the chip 308.

In various embodiments, one or more electronic components may be formed on and/or adjacent to the bottom surface 302a and/or the top surface 302b of the chip 302. In various embodiments, one or more electronic components may be formed on and/or adjacent to the bottom surface 308a and/or the top surface 308b of the chip 308.

In various embodiments, the connecting chip 304 may be a prefabricated via array for forming part of the vertical interconnects and passive circuit. The connecting chip 304 may be, for example, diced individually from a plurality of connecting chips formed on a wafer, to the required number of vias 306 and/or design.

In various embodiments, the connecting chip 304 may be optionally grinded to the required thickness and/or to expose the vias 306, where required. The grinding process may be carried out so as to align the bottom connecting chip surface 304a to be at least substantially coplanar with the bottom surface 302a of the chip 302 and/or the bottom surface 308a of the chip 308. The grinding process may also be carried out so as to align the top connecting chip surface 304b to be at least substantially coplanar with the top surface 302b of the chip 302 and/or the top surface 308b of the chip 308. The grinding process may be carried out prior to embedding the connecting chip 304 in the wafer level package 300 and/or after embedding the connecting chip 304 in the wafer level package 300.

The wafer level package 300 further includes a bottom redistribution layer (RDL) (first RDL) 320 formed between the bottom connecting chip surface 304a of the connecting chip 304 and the bottom surface 302a of the chip 302, such that the bottom RDL 320 may electrically couple one or more TSVs 306 to the chip 302, for example to one or more electrical components on and/or adjacent to the bottom surface 302a of the chip 302. The wafer level package 300 further includes one or more electrical contacts 321 in electrical communication with the bottom RDL 320.

The wafer level package 300 further includes a top redistribution layer (RDL) (second RDL) 322 formed between the top connecting chip surface 304b of the connecting chip 304 and the top surface 302b of the chip 302, such that the top RDL 322 may electrically couple one or more TSVs 306 to the chip 302, for example to one or more electrical components on and/or adjacent to the top surface 302b of the chip 302.

The bottom RDL 320 and the top RDL 322 may allow electrical coupling of one or more electrical components on and/or adjacent to the bottom surface 302a and the top surface 302b of the chip 302 to one another, by means of one or more TSVs 306 of the connecting chip 304.

The bottom RDL 320 and the top RDL 322 may be electrically coupled to the same or different TSVs 306, and/or different number of TSVs 306. In embodiments where the bottom RDL 320 and the top RDL 322 are electrically coupled to the same TSVs 306, the bottom RDL 320 and the top RDL 322 may be electrically coupled to the same or different numbers of TSVs 306.

The wafer level package 300 further includes a bottom redistribution layer (RDL) (third RDL) 330 formed between the bottom connecting chip surface 304a of the connecting chip 304 and the bottom surface 308a of the chip 308, such that the bottom RDL 330 may electrically couple one or more TSVs 306 to the chip 308, for example to one or more electrical components on and/or adjacent to the bottom surface 308a of the chip 308. The wafer level package 300 further includes one or more electrical contacts 331 in electrical communication with the bottom RDL 330.

The wafer level package 300 further includes a top redistribution layer (RDL) (fourth RDL) 332 formed between the top connecting chip surface 304b of the connecting chip 304 and the top surface 308b of the chip 308, such that the top RDL 332 may electrically couple one or more TSVs 306 to the chip 308, for example to one or more electrical components on and/or adjacent to the top surface 308b of the chip 308.

The bottom RDL 330 and the top RDL 332 may allow electrical coupling of one or more electrical components on and/or adjacent to the bottom surface 308a and the top surface 308b of the chip 308 to one another, by means of one or more TSVs 306 of the connecting chip 304.

The bottom RDL 330 and the top RDL 332 may be electrically coupled to the same or different TSVs 306, and/or different number of TSVs 306. In embodiments where the bottom RDL 330 and the top RDL 332 are electrically coupled to the same TSVs 306, the bottom RDL 330 and the top RDL 332 may be electrically coupled to the same or different numbers of TSVs 306.

In various embodiments, the bottom RDL 320 and the top RDL 322 may be electrically coupled to the same or different TSVs 306 as that of the bottom RDL 330 and the top RDL 332.

In various embodiments, the bottom RDL 320, the top RDL 322, the bottom RDL 330 and the top RDL 332 may allow electrical coupling of one or more electrical components on and/or adjacent to the bottom surface 302a and the top surface 302b of the chip 302, and one or more electrical components on and/or adjacent to the bottom surface 308a and the top surface 308b of the chip 308 to one another, by means of one or more TSVs 306 of the connecting chip 304.

In various embodiments, the wafer level package 300 may further include additional redistribution layers 340, for example for electrical coupling of the chips 302, 308, to other chips or devices within the wafer level package 300 or to external chips or devices. In various embodiments, the wafer level package 300 may further include additional one or more electrical contacts 342.

In various embodiments, the redistribution layers (RDLs) 320, 322, 330, 332, 340, may be formed after the grinding process of the connecting chip 304.

In various embodiments, the wafer level package 300 further includes a mold compound 350 configured to at least partially encapsulate the chips 302, 308, and the connecting chip 304. The mold compound 350 may be used to provide support to the connecting chip 304 and the chips 302, 308, and to the overall wafer level package 300. In various embodiments, the mold compound 350 may be made of epoxy, for example the epoxy molding compound R4212 (from Nagase) may be used for the mold compound 350.

It should be appreciated that while the mold compound 350 partially encapsulates the chips 302, 308, and the connecting chip 304 on the sidewalls of the respective chips, the mold compound 350 may also encapsulate the top surface or bottom surface of the respective chips. For example, the mold compound 350 may encapsulate the chip 302 on the bottom surface 302a or the top surface 302b of the chip 302, for example the top surface 302b may be within the mold compound 350 and not coplanar with the top surface of the mold compound 350. This may similarly apply to the chip 308 and/or the connecting chip 304.

While FIG. 3 shows two device chips 302, 308, and one connecting chip 304, it should be appreciated that the wafer level package 300 may include any number of device chip (including one device chip 302 or 308) and/or connecting chip, in any locations and/or configurations in the wafer level package 300, depending on package design and configuration, and/or applications.

The number of vertical interconnect (i.e. connecting chip) may be less than the number of device chips or the number of the device electrical input/output (I/O), for example as shown in FIG. 3, where one connecting chip is employed. However, multiple or a plurality of connecting chips may also be employed, for example around a device chip or device chip edges to provide multiple vertical interconnects. Each of the plurality of connecting chips employed may have the same or different designs or configurations, for example in terms of the arrangement, the number and/or the dimensions of the TSVs of the connecting chip.

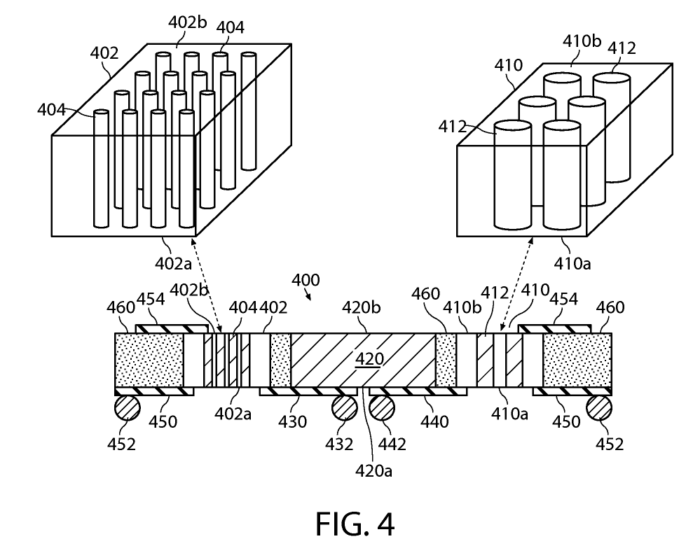

FIG. 4 shows a cross sectional view of a wafer level package 400, according to various embodiments. The wafer level package 400 may be a through-silicon via (TSV) EMWLP integrated structure (e.g. an EMWLP structure integrated with TSV). Such a wafer level package 400 may provide a high density of vias, a smaller overall package dimension and a simpler fabrication process. Features or components of the wafer level package 400 that are similarly present in the wafer level package 300 may be as described in the context of wafer level package 300.

The wafer level package 400 includes a first connecting chip (e.g. a TSV chip) 402 and a second connecting chip (e.g. a TSV chip) 410, each having different chip designs. This may provide electrical design flexibility for circuit integration. It should be appreciated that, depending on the package design, multiple via arrays (TSV chips) with different via designs may be integrated.

In the embodiment shown in FIG. 4, each of the first connecting chip 402 and the second connecting chip 410 is a through-silicon via (TSV) chip including a plurality of through-silicon vias (TSVs), for example as represented by 404 and 412 respectively, having an at least substantially circular shape or cross-section. The plurality of TSVs 404, 412, may be arranged in a two-dimensional pattern or grid pattern. The plurality of TSVs 404 have different diameters and pitches to the plurality of TSVs 412, for example the plurality of TSVs 404 have smaller diameters.

The wafer level package 400 further includes a chip (e.g. a device or device chip) 420. The chip 420 may include one or more electronic components (not shown). As shown in FIG. 4, the chip 420 may be embedded or sandwiched between the first connecting chip 402 and the second connecting chip 410, where the first connecting chip 402 and the second connecting chip 410 may be used to provide electrical vertical interconnections for one or two sides (e.g. two opposed sides) of the substrate of the chip 420.

The first connecting chip 402 includes two opposed surfaces such as a bottom connecting chip surface 402a and a top connecting chip surface 402b, where the plurality of vias 404 may be exposed through the bottom connecting chip surface 402a and the top connecting chip surface 402b. The second connecting chip 410 includes two opposed surfaces such as a bottom connecting chip surface 410a and a top connecting chip surface 410b, where the plurality of vias 412 may be exposed through the bottom connecting chip surface 410a and the top connecting chip surface 410b. The chip 420 includes two opposed connecting chip surfaces, such as a bottom surface 420a and a top surface 420b.

As shown in FIG. 4, the bottom connecting chip surface 402a of the first connecting chip 402 is at least substantially coplanar with the bottom surface 420a of the chip 420. The top connecting chip surface 402b of the first connecting chip 402 is at least substantially coplanar with the top surface 420b of the chip 420.

As shown in FIG. 4, the bottom connecting chip surface 410a of the second connecting chip 410 is at least substantially coplanar with the bottom surface 420a of the chip 420. The top connecting chip surface 410b of the second connecting chip 410 is at least substantially coplanar with the top surface 420b of the chip 420.

In various embodiments, one or more electronic components may be formed on and/or adjacent to the bottom surface 420a and/or the top surface 420b of the chip 420.

In various embodiments, each of the first connecting chip 402 and the second connecting chip 410 may be a prefabricated via array for forming part of the vertical interconnects and passive circuit. Each of the first connecting chip 402 and the second connecting chip 410 may be, for example, diced individually from a plurality of connecting chips formed on a wafer, to the required number of vias and/or design.

In various embodiments, each of the first connecting chip 402 and the second connecting chip 410 may be optionally grinded to the required thickness and/or to expose the vias 404 and 412 respectively, where required. The grinding process may be carried out so as to align the bottom connecting chip surface 402a, the bottom surface 420a and the bottom connecting chip surface 410a to be at least substantially coplanar. The grinding process may also be carried out so as to align the top connecting chip surface 402b, the top surface 420b and the top connecting chip surface 410b to be at least substantially coplanar. The grinding process may be carried out prior to embedding the first connecting chip 402 and the second connecting chip 410 in the wafer level package 400 and/or after embedding the first connecting chip 402 and the second connecting chip 410 in the wafer level package 400.

The wafer level package 400 further includes a bottom redistribution layer (RDL) (first RDL) 430 formed between the bottom connecting chip surface 402a of the first connecting chip 402 and the bottom surface 420a of the chip 420, such that the bottom RDL 430 may electrically couple one or more TSVs 404 to the chip 420, for example to one or more electrical components on and/or adjacent to the bottom surface 420a of the chip 420. The wafer level package 400 further includes one or more electrical contacts 432 in electrical communication with the bottom RDL 430.

While not shown, the wafer level package 400 may include a top redistribution layer (RDL) (second RDL) formed between the top connecting chip surface 402b of the first connecting chip 402 and the top surface 420b of the chip 420, such that the top RDL may electrically couple one or more TSVs 404 to the chip 420, for example to one or more electrical components on and/or adjacent to the top surface 420b of the chip 420.

The bottom RDL 430 and the top RDL (not shown) may allow electrical coupling of one or more electrical components on and/or adjacent to the bottom surface 420a and the top surface 420b of the chip 420 to one another, by means of one or more TSVs 404 of the first connecting chip 402.

The bottom RDL 430 and the top RDL (not shown) may be electrically coupled to the same or different TSVs 404, and/or different number of TSVs 404. In embodiments where the bottom RDL 430 and the top RDL are electrically coupled to the same TSVs 404, the bottom RDL 430 and the top RDL may be electrically coupled to the same or different numbers of TSVs 404.

The wafer level package 400 further includes a bottom redistribution layer (RDL) 440 formed between the bottom connecting chip surface 410a of the second connecting chip 410 and the bottom surface 420a of the chip 420, such that the bottom RDL 440 may electrically couple one or more TSVs 421 to the chip 420, for example to one or more electrical components on and/or adjacent to the bottom surface 420a of the chip 420. The wafer level package 400 further includes one or more electrical contacts 442 in electrical communication with the bottom RDL 440.

While not shown, the wafer level package 400 may include a top redistribution layer (RDL) formed between the top connecting chip surface 410b of the second connecting chip 410 and the top surface 420b of the chip 420, such that the top RDL may electrically couple one or more TSVs 412 to the chip 420, for example to one or more electrical components on and/or adjacent to the top surface 420b of the chip 420.

The bottom RDL 440 and the top RDL (not shown) may allow electrical coupling of one or more electrical components on and/or adjacent to the bottom surface 420a and the top surface 420b of the chip 420 to one another, by means of one or more TSVs 412 of the second connecting chip 410.

The bottom RDL 440 and the top RDL (not shown) may be electrically coupled to the same or different TSVs 412, and/or different number of TSVs 412. In embodiments where the bottom RDL 440 and the top RDL are electrically coupled to the same TSVs 412, the bottom RDL 440 and the top RDL may be electrically coupled to the same or different numbers of TSVs 412.

In various embodiments, one or more electrical components on and/or adjacent to the bottom surface 420a and/or the top surface 420b of the chip 420 may be electrically coupled to the first connecting chip 402 or the second connecting chip 410 or to both connecting chips 402, 410.

In various embodiments, the bottom RDL 430, the top RDL between the top connecting chip surface 402b of the first connecting chip 402 and the top surface 420b of the chip 420, the bottom RDL 440 and the top RDL between the top connecting chip surface 410b of the second connecting chip 410 and the top surface 420b of the chip 420 may allow electrical coupling of one or more electrical components on and/or adjacent to the bottom surface 420a and the top surface 420b of the chip 420 to one another, by means of one or more TSVs 404 of the first connecting chip 402 and/or one or more TSVs 412 of the second connecting chip 410.

In various embodiments, the wafer level package 400 may further include additional bottom redistribution layers 450, for example for electrical coupling of the first connecting chip 402 and/or the second connecting chip 410, to other chips or devices within the wafer level package 400 or to external chips or devices. In various embodiments, the wafer level package 400 may further include additional one or more electrical contacts 452.

In various embodiments, the wafer level package 400 may further include additional top redistribution layers 454, for example for electrical coupling of the first connecting chip 402 and/or the second connecting chip 410, to other chips or devices within the wafer level package 400 or to external chips or devices.

In various embodiments, the redistribution layers (RDLs) 430, 440, 450, 454, may be formed after the grinding process of the first connecting chip 402 and/or the second connecting chip 410.

In various embodiments, the wafer level package 400 further includes a mold compound 460 configured to at least partially encapsulate the first connecting chip 402, the second connecting chip 410 and the chip 420. The mold compound 460 may be used to provide support to the first connecting chip 402, the second connecting chip 410 and the chip 420, and to the overall wafer level package 400. In various embodiments, the mold compound 460 may be made of epoxy, for example the epoxy molding compound R4212 (from Nagase) may be used for the mold compound 460.

It should be appreciated that while the mold compound 460 partially encapsulates the first connecting chip 402, the second connecting chip 410 and the chip 420 on the sidewalls of the respective chips, the mold compound 460 may also encapsulate the top surface or bottom surface of the respective chips. For example, the mold compound 460 may encapsulate the first connecting chip 402 on the bottom connecting chip surface 402a or the top connecting chip surface 402b of the first connecting chip 402, for example the top connecting chip surface 402b may be within the mold compound 460 and not coplanar with the top surface of the mold compound 460. This may similarly apply to the second connecting chip 410 and the chip (device chip) 420.

While FIG. 4 shows two connecting chips 402, 410, and one device chip 420, it should be appreciated that the wafer level package 400 may include any number of device chip and/or connecting chip (including either the first connecting chip 402 or the second connecting chip 410), in any locations and/or configurations in the wafer level package 400, depending on package design and configuration, and/or applications.

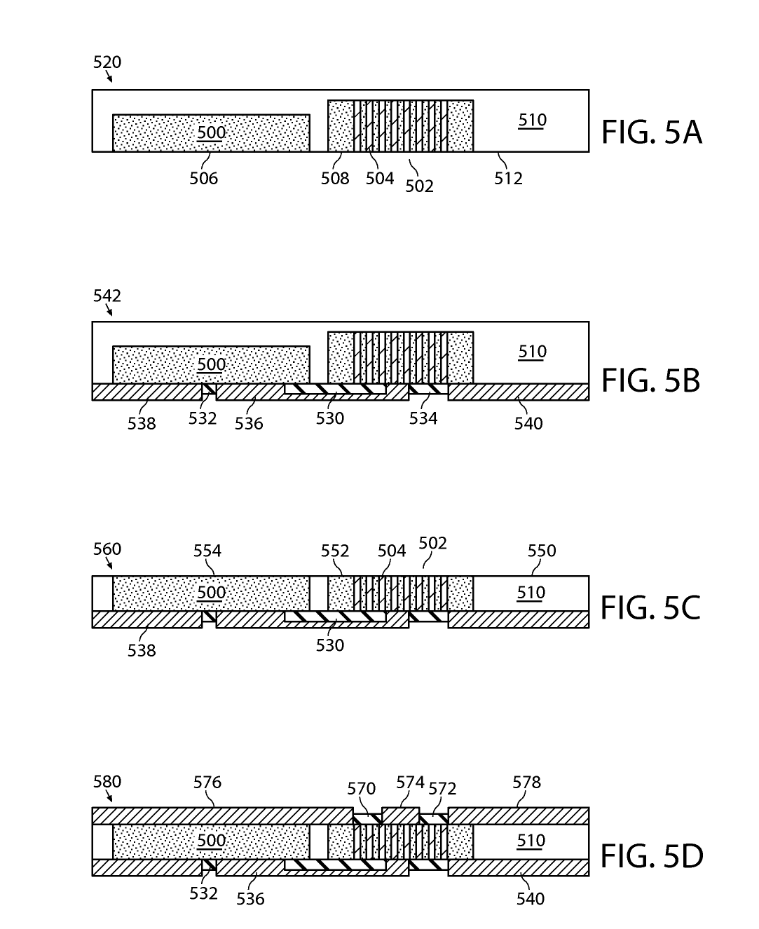

The fabrication process to form the wafer level package, for example 300 (FIG. 3), 400 (FIG. 4) (e.g. TSV integrated with EMWLP) of various embodiments will now be described by way of the following non-limiting example and with reference to FIGS. 5A to 5D. The fabrication process does not require additional process during the integration process and is compatible with current EMWLP processes.

A chip (e.g. a device chip) 500 and a connecting chip (e.g. a TSV chip) 502 having a plurality of through-silicon vias, as represented by 504 for one via, are embedded within a mold compound 510. The chip 500 and/or the connecting chip 502 may be prefabricated. The chip 500 and the connecting chip 502 may have different thicknesses.

The chip 500 and the connecting chip 502 may be embedded within the mold compound 510 such that the bottom surface 506 of the chip 500 and the bottom connecting chip surface 508 are at least substantially coplanar with each other and also with the bottom surface 512 of the mold compound 510. A structure 520 as shown in FIG. 5A may be obtained.

It should be appreciated that in some embodiments, the chip 500 and the connecting chip 502 may be fully embedded within the mold compound 510 and a grinding process may be performed to grind the front end of the embedded structure to expose the bottom surface 506 and the bottom connecting chip surface 508 through the mold compound 510 to obtain the structure 520.

Metal interconnections or lines, i.e. redistribution lines (RDLs), and one or more passivation layers may then be formed over the bottom surface of the mold wafer structure 520. A bottom RDL 530 may be formed between the bottom surface 506 of the chip 500 and the bottom connecting chip surface 508 to electrically couple the chip 500 with the connecting chip 502. The bottom RDL 530 is electrically coupled to the plurality of vias 504. Additional bottom RDLs 532, 534, may be formed respectively on the bottom surface 506 and the bottom connecting chip surface 508, for example for electrical coupling to other chips or devices within the mold compound 510, or to external chips or devices. The bottom RDL 532 may also be used for electrical coupling among electronic components (not shown) formed on the bottom surface 506 of the chip 500, while the bottom RDL 534 may also be used for electrical coupling among different vias 504.

Passivation layers 536, 538, 540 may be formed to passivate or insulate the remaining surfaces of the bottom surface 506, the remaining surfaces of the bottom connecting chip surface 508 and the bottom surface 512 of the mold compound 510. Passivation layer 536 may be formed over the bottom RDL 530 to insulate the bottom RDL 530. A structure 542 as shown in FIG. 5B may be obtained.

A backgrind process may be carried out on the structure 542 in order to expose the plurality of vias 504 through the top surface 550 of the mold compound 510. In other words, the backgrind process is carried out to remove material of the mold compound 510 and/or material of the connecting chip 502 such that the top surface 550 of the mold compound 510 and the top connecting chip surface 552 are at least substantially coplanar. The backgrind process may also be performed so as to obtain a top surface 554 of the chip 500 to be at least substantially coplanar with the top surface 550 and the top connecting chip surface 552. A structure 560 as shown in FIG. 5C may be obtained.

It should be appreciated that in some embodiments, the backgrind process may be performed prior to forming the bottom RDLs 530, 532, 534, and the passivation layers 536, 538, 540.

Metal interconnections or lines, i.e. redistribution lines (RDLs), and one or more passivation layers may then be formed over the top surface of the structure 560. Top RDLs 570, 572, may be formed on the top connecting chip surface 552, for example for electrical coupling among different vias 504 and for electrical coupling to other chips or devices within the mold compound 510, or to external chips or devices.

Passivation layers 574, 576, 578 may also be formed to passivate or insulate the remaining surfaces of the top connecting chip surface 552, the top surface 554 of the chip 500 and the top surface 550 of the mold compound 510. A structure 580 as shown in FIG. 5D may be obtained.

It should be appreciated that in some embodiments, a top RDL may be formed between the top surface 554 of the chip 500 and the top connecting chip surface 552. In addition, a top RDL may also be formed on the top surface 554, for example for electrical coupling among electronic components (not shown) formed on the top surface 554 of the chip 500.

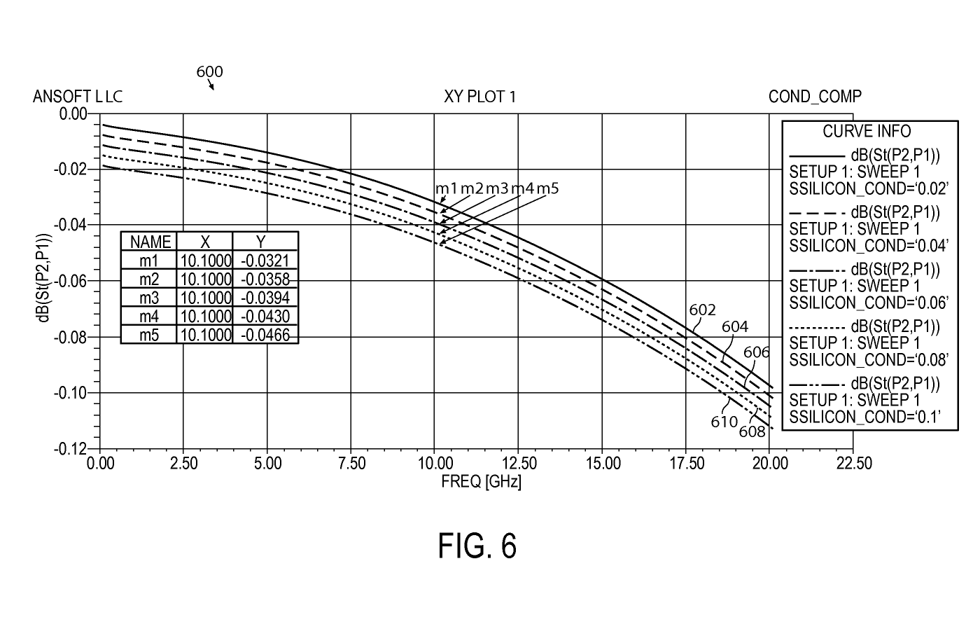

In various embodiments, ground vias and signal vias may be defined or formed for the plurality of vias (TSVs) of the connecting chip. For example, a set of three vias may be employed as ground-signal-ground vias (i.e. one signal via and two ground vias). The performance of the ground-signal-ground (GSG) vias in the TSV connecting chip was simulated and the results are as shown in the plot 600 of FIG. 6 for different silicon substrate conductivities or correspondingly different silicon substrate resistivities. The plot 600 shows the results for conductivities of 0.02 S cm⁻¹ (m1) 602, 0.04 S cm⁻¹ (m2) 604, 0.06 S cm⁻¹ (m3) 606, 0.08 S cm⁻¹ (m4) 608 and 0.1 S cm⁻¹ (m5) 610 respectively.

Each of the via of the GSG vias has a diameter of about 50 μm and the GSG vias have a pitch of about 150 μm. The length or height of each TSV is about 300 μm, which is more than the typical die thickness of around 250 μm.

The results of FIG. 6 show that for a standard silicon (Si) wafer of a resistivity of about 10Ω·cm used to fabricate the TSV chip, it has a loss of less than 0.05 dB and 0.12 dB at about 10 GHz and about 20 GHz, respectively. The results show that the TSV has a maximum loss of <0.15 dB at about 20 GHz. These results show that the TSV chip may be capable of supporting most of the current digital and analog applications.

As shown in the results of FIG. 6, the insertion loss of the TSV chip increases as the frequency increases, which follows a similar trend as all electrical interconnects. The loss for the TSV chip is mostly from the lossy Si substrate. This may be reduced by using a high resistivity Si wafer, which the cost has come down recently. This may be useful especially for high frequency applications. For example, in various embodiments, the silicon wafer or chip (i.e. the connecting chip) may have a resistivity of between about 1000 Ω·cm and about 10000 Ω·cm.

In various embodiments, the connecting chip (i.e. the TSV chip) may be configured to form part of a 3D passive circuit, as a component including but not limited to, a filter, a diplexer, a resonator, a balun, a coupler, an antenna or a radiating element.

As an example and not limitation, the following is an exemplary design of a cavity filter. Depending on the circuit, the TSVs of the TSV chip may be designed to form the vertical electrical wall of the cavity on the Si substrate of the TSV chip. The passive circuit may have an input and an output on opposite sides of the TSV chip, thereby providing 3D interconnects.

The dimension of the cavity for filter design may be given by the following equation:

$${f}_{mnl} = \frac{c}{2 \sqrt{{ɛ}_{r}}} \sqrt{{( \frac{m}{L} )}^{2} + {( \frac{n}{H} )}^{2} + {( \frac{l}{W} )}^{2}} \qquad ( Equation 1 )$$

where fₘₙₗ is the resonant frequency of the cavity filter/resonator with the subscript letters “m”, “n” and “l” indicating the resonance modes, L is the length, W is the width and H is the height (thickness) of the cavity, ᵣ is the dielectric constant of the substrate (e.g. ᵣ(Silicon)=11.9), c is the speed of light.

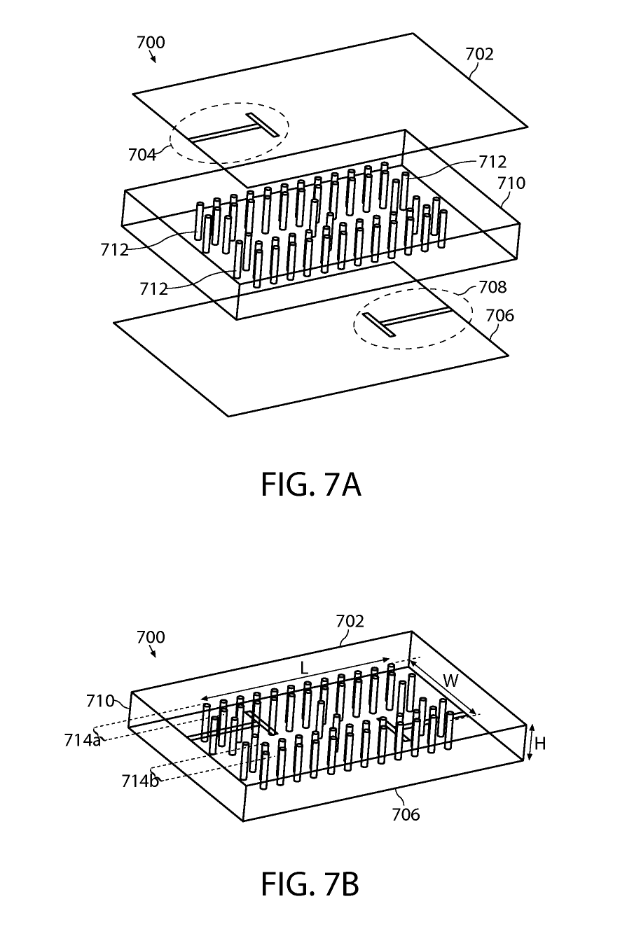

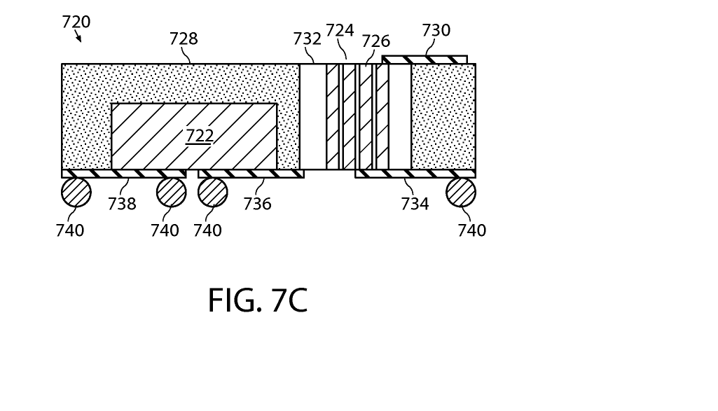

In order to minimise or prevent leakage of the electrical signal between the TSVs, multiple rows of the TSVs may be designed. In various embodiments, the design of a cavity filter using a connecting chip (i.e. TSV chip) may be as shown in FIGS. 7A and 7B.

FIGS. 7A and 7B show respectively a perspective exploded view and a perspective view, when assembled, of a filter 700, according to various embodiments. The filter (e.g. embedded/integrated TSV cavity filter) 700 includes a top metal line or redistribution line (RDL) 702, including a top input/output (I/O) filter port 704, a bottom metal line or redistribution line (RDL) 706, including a bottom input/output (I/O) filter port 708, and a connecting chip (TSV chip) 710 of a silicon substrate sandwiched between the top RDL 702 and the bottom RDL 706. The TSV chip 710 includes a plurality of through-silicon vias (TSVs), as represented by 712 for three vias. A pair 714a, 714b, of two rows of TSVs may be designed to form the electrical sidewalls of the cavity.

In various embodiments, the top or bottom or both the metallization of the cavity are formed by the RDL layers 702, 706, during the molding/embedding process. The Si chip 710 includes the TSVs 712 which may be designed to form the electrical walls of the cavity based on the dimension as given in Equation 1. The design of the circuit input and output connections may be on the top and bottom sides of the cavity. In this way, the electrical signal may be connected to both sides through the filter (i.e. the TSV chip), by means of the TSVs 712.

In various embodiments, as the performance of the filter may be affected by the height of the cavity, as shown in FIG. 7C, it is possible for the design of the wafer level package (e.g. EMWLP) 720 to incorporate a chip or device chip 722 having a different height/thickness compared to that of the TSV chip 724 incorporating the cavity filter having a plurality of TSVs 726, as shown in FIG. 7C. The chip 722 and the TSV chip 724 are embedded in a mold compound 728.

The wafer level package 720 may include top RDLs, e.g. a top RDL 730 over the top connecting chip surface 732 of the TSV chip 724, and bottom RDLs, e.g. 734, 736, 738 over the bottom connecting surface of the TSV chip 724 and the bottom surface of the chip 722. The wafer level package 720 may include a plurality of electrical contacts 740, e.g. interconnection balls, e.g. solder balls. It should be appreciated that other designs or configurations may be employed.

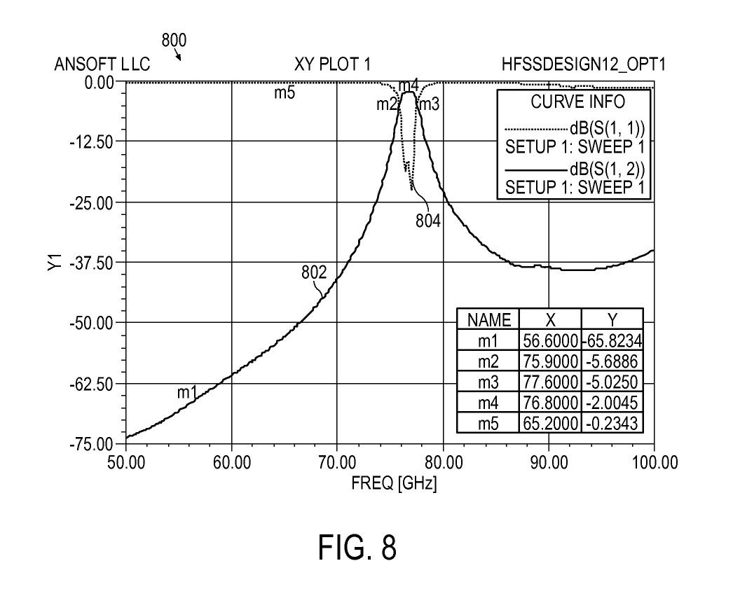

FIG. 8 shows a plot 800 of filter response of the embedded TSV cavity filter of various embodiments, where the input and output are on opposite sides of the cavity filter. The plot 800 shows the simulated transmission 802 and the simulated reflection 804 responses of the cavity filter.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. A wafer level package, comprising:
at least one chip comprising at least one electronic component; and
at least one connecting chip comprising at least one through-silicon via,
wherein the at least one through-silicon via is electrically coupled to the at least one chip.

2. The wafer level package as claimed in claim 1, further comprising a first redistribution layer between a first connecting chip surface of the at least one connecting chip and a first surface of the at least one chip, wherein the first redistribution layer is configured to electrically couple the at least one through-silicon via to the at least one chip.

3. The wafer level package as claimed in claim 2, wherein the first redistribution layer further comprises a first input/output (I/O) port.

4. The wafer level package as claimed in claim 2, further comprising a second redistribution layer between a second connecting chip surface of the at least one connecting chip and a second surface of the at least one chip, wherein the second redistribution layer is configured to electrically couple the at least one through-silicon via to the at least one chip.

5. The wafer level package as claimed in claim 4, wherein the second redistribution layer further comprises a second input/output (I/O) port.

6. The wafer level package as claimed in claim 4, wherein the first redistribution layer and the second redistribution layer comprise a conductive material.

7. The wafer level package as claimed in claim 4, wherein the first connecting chip surface and the first surface of the at least one chip are at least substantially coplanar and wherein the second connecting chip surface and the second surface of the at least one chip are at least substantially coplanar.

8. The wafer level package as claimed in claim 2, further comprising at least one electrical contact in electrical communication with the first redistribution layer.

9. The wafer level package as claimed in claim 1, wherein the at least one through-silicon via has an aspect ratio of between about 1:2 and about 1:10.

10. The wafer level package as claimed in claim 1, wherein the at least one through-silicon via has a diameter of between about 10 μm and about 100 μm.

11. The wafer level package as claimed in claim 1, wherein the at least one through-silicon via has a height of between about 100 μm and about 400 μm.

12. The wafer level package as claimed in claim 1, wherein the connecting chip has a resistivity of between about 1000 Ω·cm and about 10000 Ω·cm.

13. The wafer level package as claimed in claim 1, wherein the at least one through-silicon via of the at least one connecting chip comprises a plurality of through-silicon vias.

14. The wafer level package as claimed in claim 13, wherein the plurality of through-silicon vias has a pitch of between about 40 μm and about 500 μm.

15. The wafer level package as claimed in claim 13, wherein the at least one connecting chip is configured to function as a filter, or a diplexer, or a resonator, or a balun, or a coupler, or an antenna or a radiating element.

16. The wafer level package as claimed in claim 1, further comprising a mold compound configured to at least partially encapsulate the at least one chip and the at least one connecting chip.

17. The wafer level package as claimed in claim 1, wherein the at least one electronic component comprises an electronic circuit.

18. The wafer level package as claimed in claim 17, wherein the electronic circuit comprises at least one active electronic element.

19. The wafer level package as claimed in claim 17, wherein the electronic circuit comprises at least one electronic element selected from a group of electronic elements consisting of:
a transistor,
a diode,
a thyristor,
a capacitor,
an inductor,
a transformer,
a resistor, and a combination thereof.

20. The wafer level package as claimed in claim 1, wherein the connecting chip is free of any electronic component.
